(19) United States
(12) Patent Application Publication
(10) Pub. No.: US 2009/0289257 A1
(43) Pub. Date: Nov. 26, 2009

(54) EXPOSURE MASK USING GRAY-TONE PATTERN, MANUFACTURING METHOD OF TFT SUBSTRATE USING THE SAME AND LIQUID CRYSTAL DISPLAY DEVICE HAVING THE TFT SUBSTRATE

(75) Inventor: Hiroshi SAKURAI, Kanagawa (JP)

Correspondence Address: YOUNG & THOMPSON, 209 Madison Street, Suite 500, ALEXANDRIA, VA, 22314, US

(73) Assignee: NEC LCD Technologies, Ltd., Kanagawa (JP)

(21) Appl. No.: 12/469,186

(22) Filed: May 20, 2009

(30) Foreign Application Priority Data
May 20, 2008 (JP) 2008-131798

(51) Int. Cl. H01L 33/00; G03F 1/00; H01L 21/28

(52) U.S. Cl. 257/59; 430/5; 438/585; 257/E33.053; 257/E21.19

(57) ABSTRACT

Disclosed are an exposure mask capable of improving uniformity of a resist film thickness of a half film thickness part and reducing a display defect to increase a manufacturing yield, a method of manufacturing a TFT substrate using the exposure mask and a liquid crystal display comprising the TFT substrate manufactured by the method and having no display defect. The exposure mask includes a light-shielding pattern on a transparent substrate in which a gray-tone area is provided to at least a part of the light-shielding pattern, the gray-tone area having an oblong light-shielding pattern having a width of a submarginal resolution of an exposure apparatus and sandwiched between oblong slit-type transmissive patterns having a width of the submarginal resolution, and a light-shielding rate of the gray-tone area is gradually reduced toward a center of the oblong light-shielding pattern from longitudinal ends thereof.

This application is based upon and claims the benefit of priority from Japanese patent application No. 2008-131798, filed on May 20, 2008, the disclosure of which is incorporated herein in its entirety by reference.

### TECHNICAL FIELD

The present invention relates to exposure mask using a gray-tone pattern capable of improving a thickness uniformity of thinner thickness resist film of a channel area (i.e., an area between source and drain electrodes) of a Thin Film Transistor (hereinafter, referred to as TFT) to enhance a manufacturing yield in a method of manufacturing a transistor array substrate for a liquid crystal display wherein source and drain wiring patterns and an island pattern of an active area are formed in a single photolithography process. The present invention also relates to a method of manufacturing an array substrate (TFT substrate) for a liquid crystal display using the exposure mask using a gray-tone pattern and a liquid crystal display having the TFT substrate manufactured by the method.

### BACKGROUND ART

In recent years, a liquid crystal display is widely used as a high resolution display. The liquid crystal display holds liquid crystal material between a TFT substrate having switching devices such as TFT formed thereon and a color filter substrate having color layers and a black matrix formed thereon. In addition, the liquid crystal display applies an electric field between the electrodes provided to each of the TFT substrate and the color filter substrate or between the electrodes provided in the TFT substrate to change orientation directions of liquid crystal molecules, and controls an amount of a light transmission with each image pixel from light source.

The spread of this liquid crystal display has also strongly required making advanced function and the cost reduction. Further, attempts to realize the cost reduction are being made by improving a manufacturing yield of the TFT substrate or introducing an innovative manufacturing process into the manufacturing method.

In general, the conventional manufacturing methods of the TFT substrate need five photolithography processes. However, since the demand for the cost reduction is recently strong, a method is adopted which once obtains an objected resist film having a multi-thin thickness film (hereinafter, referred to as half film thickness) part by using a multiple-tone mask in a part of the manufacturing process. Thereby, the number of process reduction is realized and a process of completing the TFT array by four photolithography processes is used in the mass production.

The multiple-tone mask is classified into two types: a gray-tone mask and a half tone mask. The gray-tone mask has a pattern of slit space part (light transmissive pattern) that its width is under a submarginal resolution provided by an exposure apparatus and diffracts a part of light to realize a less light exposure. In the meantime, the half-tone mask uses a semi-transparent film to perform a half exposure. Both of the masks express three exposure levels of an exposed part, a thinner exposed part and a non-exposed part by one exposure and make a resist film having two types of thickness after development. Since the semi-transparent film is used, the half tone mask is expensive. Regarding the costs, it is advantageous to use the gray-tone mask in the large size liquid crystal display because of using conventional exposure processes.

In the followings, a TFT substrate manufacturing process including a photolithography process using a gray-tone mask will be described with reference to a plan view of FIG. 1.

(1) First, a film of metal such as Cr, Mo and Al is formed on a transparent glass substrate by a sputtering method, and gate wiring 1, gate electrode 1a and a gate terminal (not shown) are formed in a first photolithography process (FIG. 1(a)).
(2) Then, a gate insulation film (SiNx), a semiconductor layer (amorphous silicon; a-Si), an ohmic contact layer (doped amorphous silicon; n⁺a-Si layer), and a film of metal such as Cr, Mo and Al are formed thereon by a CVD method, a sputtering method or the like, respectively. Subsequently, source electrode 2b, drain electrode 2a, drain wiring 2, a drain terminal (not shown) and island 3 to be a channel area are sequentially formed in a second photolithography process using a gray-tone mask (FIG. 1(b)).
(3) Then, an interlayer insulation film is formed on an entire surface and a contact hole such as source contact 4 connecting a pixel electrode to be formed in a later process with source electrode 2b is formed in a third photolithography process (FIG. 1(c)).
(4) Finally, transparent conductive material such as ITO is formed on the entire surface by the sputtering method or the like and pixel electrode 5 is formed in a fourth photolithography process (FIG. 1(d)).

The second photolithography process will be more specifically described. The second photolithography process uses a gray-tone mask.

The gray-tone mask is provided on a transparent substrate with a light-shielding film pattern to perform whole light-shielding and a slit part to perform medium exposure, as described above. As shown in FIG. 2, the gray-tone mask for manufacturing a TFT substrate is a mask in which slits (light-transmissive parts) 22 of the width under a submarginal resolution provided by the exposure apparatus and a fine mask pattern (light-shielding part) 21a are arranged at a channel island pattern position of light-shielding film pattern 21 formed as a wiring pattern. When performing an exposure process using the mask, the light transmits through the part having no mask pattern. When positive sensitive resist (hereinafter referred as “resist”) is used, all the exposed resist is removed by a later development process (whole light transmissive quantity part). The light is entirely shielded at the part having the mask pattern (wiring pattern part) in which the resist having the initial film thickness remains as it is even after the development. Meanwhile, at the part (channel island pattern) in which the slit space (hereinafter referred as “slit”) of the submarginal resolution and the fine pattern are alternately arranged, the light is diffracted and the light having a less quantity than that at the whole transmissive part reaches the resist. As a result, an exposure value of less light quantity is smaller as compared to the whole transmissive part, so that the resist having thinner film thickness to the initial film thickness can be remained on the substrate after the development. The exposure value can be controlled by adjusting a slit width. When the gray-tone mask is used as described above, the remaining film of the resist can be patterned into three stages of a part where the resist having the initial film thickness remains as it is (thick film part), a part where the resist having a medium film thickness thinner than the thick film part remains (hereinafter, referred to as half film thickness part) and a part where all the resist is removed.

The gray-tone mask pattern of performing the diffraction exposure so as to form the channel island when manufacturing the TFT substrate has a gray-tone area arranged at a part corresponding to a channel area, as shown in FIG. 2. For example, a resolution limit of a usual exposure apparatus is about 3.5-4.0 μm. Thus, it is preferred that a slit width (W1)/fine pattern width (W2)/a slit width (W3) are made to be about 1.0-1.6 μm/1.0-1.6 μm/1.0-1.6 μm, with respect to the slit pattern of the submarginal resolution of the gray-tone area and the fine pattern (refer to FIG. 2(b) that is a partial enlarged view of FIG. 2(a)).

The second photolithography process using the exposure mask having the above pattern will be described with reference to sectional views for each process.

First, as shown in FIG. 1(a), after patterning the gate wiring including gate electrode 11, SiNx (Silicon Nitride) film 12 to be a gate insulation film, a-Si layer 13, n⁺a-Si layer 14 and a metal layer 15 are sequentially formed.

Resist is applied to be a predetermined film thickness on the entire surface and is exposed through gray-tone mask 17 having light-shielding film pattern 17b on transparent substrate 17a. As a result, the resist at parts having no light-shielding film pattern is exposed over the entire film thickness thereof, so that it becomes an entirely exposed area 16b, and the resist at parts having the light-shielding film pattern is not exposed, so that it becomes a non-exposed area (thick film part) 16a. At the channel island (gray-tone) area Gr, the exposure is limited, so that the corresponding resist becomes a half exposed area (means a thinner film thickness part) 16c in which a half of the resist film thickness is exposed (FIG. 3A). Through the development, the resist of the initial film thickness remains, as it is, at parts to be a source electrode, a drain electrode, a drain wiring and a drain terminal, the resist of the half film thickness remains at a part to be a channel of transistor, and the resist is removed at the other parts, so that first resist pattern 16 having the half film thickness is formed (FIG. 3B). Subsequently, by etching metal layer 15, n⁺a-Si layer 14 and a-Si layer 13, laminate structures 13′, 14′, 15′ to be a source electrode, a drain electrode, a drain wiring and a drain terminal are formed (FIG. 3C). Then, the resist of the half film thickness in the channel part is removed through an O₂ ashing method, so that second resist pattern 16′ is formed (FIG. 3D). Then, the exposed metal is removed by etching second metal layer 15′ and a-Si layer 13′ of the channel part is exposed by etching n⁺a-Si layer 14′. Thereby, conductive layers 14a, 15a to be a drain electrode, a drain wiring and a drain terminal and conductive layers 14b, 15b to be a source electrode are formed (FIG. 3E). Finally, by removing the resist, the second photolithography process is completed.

Further, passivation SiNx film 18 is formed by a CVD method (FIG. 3F), and a gate, an opening of the drain terminal part and contact hole 19 on the source electrode are formed in the third photolithography process (FIG. 3G). Finally, a film of ITO (Indium Tin Oxide) is formed by a sputtering method, and pixel electrode 20 is formed in the fourth photolithography process, so that an array substrate is completed (FIG. 3H).

However, the above processes using the gray-tone mask pattern need very precise control the process conditions. Particularly, it is very difficult to control the film thickness uniformity of the half film thickness part.

To be more specific, when a pattern of the resist having the half film thickness is formed by using a gray-tone mask, it was found that sectional profiles thereof are as shown in FIG. 4. FIG. 4(a) is a plan view of a resist pattern exposed and developed with the gray-tone mask of FIG. 2 (which is a partial enlarged plan view corresponding to FIG. 2(b)), FIG. 4(b) is a sectional view taken along a line of B-B′, FIG. 4(c) is a sectional view taken along a line of C-C′ and FIG. 4(d) is a sectional view taken along a line of D-D′. In other words, as shown in the sectional view of the resist film thickness in a width direction of the channel (B-B′ section: FIG. 4(b)), when comparing a film thickness T1 at a center of the resist pattern and a film thickness T2 at ends, T1 is somewhat thicker than T2. Specifically, when comparing C-C′ section of the channel end (FIG. 4(c)) and D-D′ section of the center (FIG. 4(d)), which are resist sections in a longitudinal direction of the channel, the resist of the half film thickness part is thinner at the C-C′ section than the D-D′ section. This is because the resist is more exposed at the ends than the center by the diffraction of the light from the whole transmissive part. As a result, the made channel length and shape of transistor is varied, which causes a problem on display. The larger the channel width, the higher the variation in the resist film thickness.

The resolution limit of a usual exposure apparatus that is used to manufacture a liquid crystal display is about 3.5-4.0 μm, as described above. Due to this, a width value of a slit to be inserted into a gray-tone mask is employed about 1.0-1.6 μm. Thus, the process using the gray-tone mask is a very precise process using a fine image pattern. Further, the resist film thickness of the half film thickness part is highly varied due to various factors such as resultant variation in the mask size, unevenness of each photolithography process and the like. In addition, it is often that when the transistor sizes are different between a transistor of a display part and a protection transistor of an outer peripheral part, the resist film thickness of the half film thickness part becomes different. That is, when the channel lengths of the transistors are different, the sizes of the fine patterns and slits arranged on the channel part are also different. Thus, when the photolithography is carried our in the same condition, each resist film thickness of the half film thickness part becomes different.

As described above, the resist film thickness of the channel part is thin at the end and thick at the center. However, when the resist film thickness of the channel center is thicker than the end by a predetermined level or more, a part of the resist of the half film thickness part that should be removed by O₂ ashing remains and metal pattern 41 of the channel part is shorted by the second etching of the metal layer (FIG. 5(a)), which cause point and line defects. On the contrary, when the resist of the half film thickness part is thinner than a designed level, the ends of the half film thickness part are not covered with the resist, which should be originally covered by the resist of the half film thickness. The ends, which are not covered with the resist, are exposed to the first etching of metal layer 15, which has been described with reference to FIG. 3C, and the dry etchings of n⁺a-Si layer 14 and a-Si layer 13, so that semiconductor layer 42 of the channel part is recessed as shown in FIG. 5(b), and, what is worse, is fractured as shown in FIG. 5(c), to get to causes a point defect.

As a method of improving the film thickness uniformity of the half film thickness part, Patent Document 1 (Japanese Unexamined Patent Publication No. 2002-57338) discloses that areas of transmissive parts 52a are enlarged at the channel ends of the gray-tone part sandwiched between whole light-shielding parts 51, thereby improving the uniformity of the resist half film thickness part, as shown in FIG. 6. However, this method has an opposite effect with respect to the problems (FIGS. 5(a) to 5(c)) caused due to the fact that the resist film is thinner at the channel ends and thicker at the center, and cannot improve the uniformity of the resist film thickness, as shown in FIG. 4. Furthermore, since whole light-shielding part 51, which forms source and drain electrodes, has cut portions, the final result of the channel length, which is an important factor to decide characteristics of the transistor, is varied. This is because a shape of the whole light-shielding part becomes a shape of a part in which the resist remains to be the initial film thickness and shapes of source and drain electrodes. For this reason, the characteristics of the transistor are varied, so that display irregularities may be caused.

In addition, Patent Document 2 (Japanese Unexamined Patent Publication No. 2002-55364) discloses, as measures to the terminal bending caused due to the fact that the resist film thickness is thinner at the ends of the channel part on which the gray-tone pattern is arranged, that fine patterns 61b are arranged on the upper and lower sides of fine patterns 61a of the channel part at the gray-tone part sandwiched between whole light-shielding parts 61, as shown in FIG. 7. However, according to this method, the size of the semiconductor layer is too larger, so that an aperture ratio is lowered. In addition, as measures to the terminal bending, it may be possible that both ends of fine pattern 21a are made to be protruded beyond light-shielding film pattern 21, as shown in FIG. 2. Thus, the above method does not have an effect to be expected.

Further, Patent Document 3 (Japanese Unexamined Patent Publication No. 2002-268200) discloses (fine) patterns for gray-tones, which are formed so as to make a taper angel of the resist small. However, there are provided a plurality of fine patterns in which the outer patterns are relatively wider and the central patterns are relatively thinner. In addition, the resist film is deposited several times so as to improve the uniformity of the half film thickness, so that the number of processes is increased.

Meantime, Patent Document 4 (Japanese Unexamined Patent Publication No. 2000-066371) discloses that the resist pattern is narrowed toward a center of a transparent part pattern so as to prevent a resultant shape of the resist pattern from being distorted. However, such structure is suggested to correct the variation due to expansion/constriction of the resist film in advance, thereby obtaining a designed rectangular resist pattern. In other words, the above structure has the object, means and effect different from the gray-tone mask that uses a fine pattern of submarginal exposure resolution to obtain a resist pattern of a medium film thickness. According to Patent Document 4, the variation is corrected so as to make a rectangular shape of the contact hole of the planar direction, which is formed to be an overall film thickness, rather than to solve the film thickness irregularity of the resist of the half film thickness.

### SUMMARY OF THE INVENTION

### Problem to be Solved by the Invention

The present invention has been made to solve the above problems occurring in the prior art. An object of the invention is to provide an exposure mask capable of improving uniformity of a resist film thickness of a half film thickness part and reducing a display defect due to short or disconnection to increase a manufacturing yield, a method of manufacturing a TFT substrate using the exposure mask and a liquid crystal display including the TFT substrate manufactured by the method and having no display defect.

### Means for Solving the Problems

In order to achieve at least one of the above objects, there is provided an exposure mask having a light-shielding pattern on a transparent substrate in which a gray-tone area is provided to at least a part of the light-shielding pattern, the gray-tone area including an oblong light-shielding pattern having a width of a submarginal resolution provided by an exposure apparatus and sandwiched between oblong slit-type transmissive patterns having a width of the submarginal resolution, and a light-shielding rate of the gray-tone area is gradually reduced toward a center of the oblong light-shielding pattern from longitudinal ends thereof.

As shown in FIG. 8(a), when a width of a slit-type transmissive pattern of a gray-tone pattern arranged at a channel part on an exposure mask is W and a width of the oblong light-shielding pattern (hereinafter, referred to as light-shielding fine pattern) is B, a light-shielding rate S is defined as [B/(W+B+W)]×100(%). The structure that the light-shielding rate of the gray-tone area is gradually reduced toward the center from the longitudinal ends means that it is linearly reduced toward a center from both ends (line segment A), that it is curvilinear reduced (line segment B) or that it is stepwise reduced (line segment C), and that the light-shielding rate once reduced is not increased. S_{E} denotes a light-shielding rate at an end, S_{C} indicates a light-shielding rate at a center and a ratio thereof: S_{E}/S_{C} (hereinafter, referred to as a ratio of light-shielding rates) is larger than 1. In order to enable a light-shielding rate to be reduced toward a center, a ratio of the slit-type transmissive patterns is made to be large at a center. In other words, the light-shielding fine pattern sandwiched between the slit-type transmissive patterns is patterned in such a way that a width perpendicular to a longitudinal direction is gradually narrowed in a linear or curve type toward centers of long sides of the light-shielding fine pattern from both ends of the long sides, or is alternatively patterned to have a first area in which a width perpendicular to a longitudinal direction is narrower at the centers of the long sides than both ends. Furthermore, it is possible that centers of the light-shielding patterns positioned at both sides of the gray-tone area, which centers are opposite to the longitudinal sides of the light-shielding fine pattern, are more recessed than both ends in a direction distant from the light-shielding fine pattern. In addition, it is possible that a longitudinal center of the light-shielding fine pattern is opened to provide a second transmissive pattern so as to satisfy the light-shielding rate.

In particular, the exposure mask is for manufacturing a TFT substrate wherein the gray-tone area corresponds to a channel area of the thin film transistor and the longitudinal direction of the light-shielding fine pattern is a channel width direction of the thin film transistor.

In addition, according to an exemplary embodiment of the invention, there is provided a method of manufacturing a thin film transistor substrate including:

sequentially forming a semiconductor layer and a wiring material layer on a substrate;

forming a resist film on the wiring material layer, and collectively forming overall film thickness patterns to be source and drain wiring patterns and a half film thickness pattern to be an island pattern of an active area on the resist film by using a gray-tone mask;

etching the wiring material layer and the semiconductor layer by using the resist film having the patterns formed thereon as a mask;

reducing a thickness of the film resist film to remove a resist of the half film thickness pattern part and thus to expose the wiring material layer of the half film thickness pattern part; and

etching the wiring material layer by using the remaining resist film as a mask and exposing the semiconductor layer to be an island of an active area,

wherein the above described mask is used as the gray-tone mask.

The substrate is a substrate including a gate wiring layer containing a gate electrode and a gate insulation film formed on the gate wiring layer. In addition, a thin film transistor manufactured by the method is at least one of a pixel transistor of a liquid crystal display and a protection transistor of an outer peripheral part.

Additionally, according to another exemplary embodiment of the invention, there is provided a liquid crystal display having the thin film transistor manufactured by the method.

### EFFECTS OF THE INVENTION

According to the invention, the light-shielding rate of the gray-tone area of the exposure mask is made to be higher at the longitudinal both ends of the light-shielding fine pattern than the center thereof, so that it is possible to improve the uniformity of the resist half film thickness on the substrate and to reduce the display defect, thereby improving the manufacturing yield.

### BRIEF DESCRIPTION OF THE DRAWINGS

FIG. 1 is a plan view illustrating processes of manufacturing a TFT substrate of the invention and the prior art.

FIG. 2 is a plan view illustrating a conventional gray-tone mask pattern (a) and a partial enlarged plan view (b).

FIG. 3A is a sectional view illustrating a process of manufacturing a TFT substrate of the invention and the prior art.

FIG. 3B is a sectional view illustrating a process of manufacturing a TFT substrate of the invention and the prior art.

FIG. 3C is a sectional view illustrating a process of manufacturing a TFT substrate of the invention and the prior art.

FIG. 3D is a sectional view illustrating a process of manufacturing a TFT substrate of the invention and the prior art.

FIG. 3E is a sectional view illustrating a process of manufacturing a TFT substrate of the invention and the prior art.

FIG. 3F is a sectional view illustrating a process of manufacturing a TFT substrate of the invention and the prior art.

FIG. 3G is a sectional view illustrating a process of manufacturing a TFT substrate of the invention and the prior art.

FIG. 3H is a sectional view illustrating a process of manufacturing a TFT substrate of the invention and the prior art.

FIG. 4 is a view illustrating a problem of the prior art, in which (a) is a plan view of a resist mask near a channel part, (b) is a sectional view taken along a line of B-B′ of (a), (c) is a sectional view taken along a line of C-C′ of (a) and (d) is a sectional view taken along a line of D-D′ of (a).

FIG. 5 is a plan view illustrating a problem of the prior art.

FIG. 6 is a plan view illustrating a gray-tone mask disclosed in Patent Document 1.

FIG. 7 is a plan view illustrating a gray-tone mask disclosed in Patent Document 2.

FIG. 8 is a view illustrating a light-shielding rate of a gray-tone mask related to the invention.

FIG. 9 is a plan view exemplifying shapes of a fine pattern of a gray-tone mask related to the invention.

FIG. 10 is a view illustrating shapes of a resist mask after exposure and development using a mask of the invention, in which (a) is a plan view of a resist mask near a channel part, (b) is a sectional view taken along a line of E-E′ of (a), (c) is a sectional view taken along a line of F-F′ of (a) and (d) is a sectional view taken along a line of G-G′ of (a).

FIG. 11 is a partial plan view of a liquid crystal display related to the invention.

FIG. 12 is a view illustrating an effect of the invention, in which (a) is a view illustrating a method of calculating a light-shielding rate and (b) is a view illustrating an amount of constriction of resist ends, which is a problem to be solved.

FIG. 13 is a view illustrating a relation between a ratio of light-shielding rates and an amount of constriction.

### PREFERRED EMBODIMENTS OF THE INVENTION

In the followings, the invention will be more specifically described with reference to exemplary embodiments. However, it should be noted that the invention is not limited thereto.

### Exemplary Embodiment 1

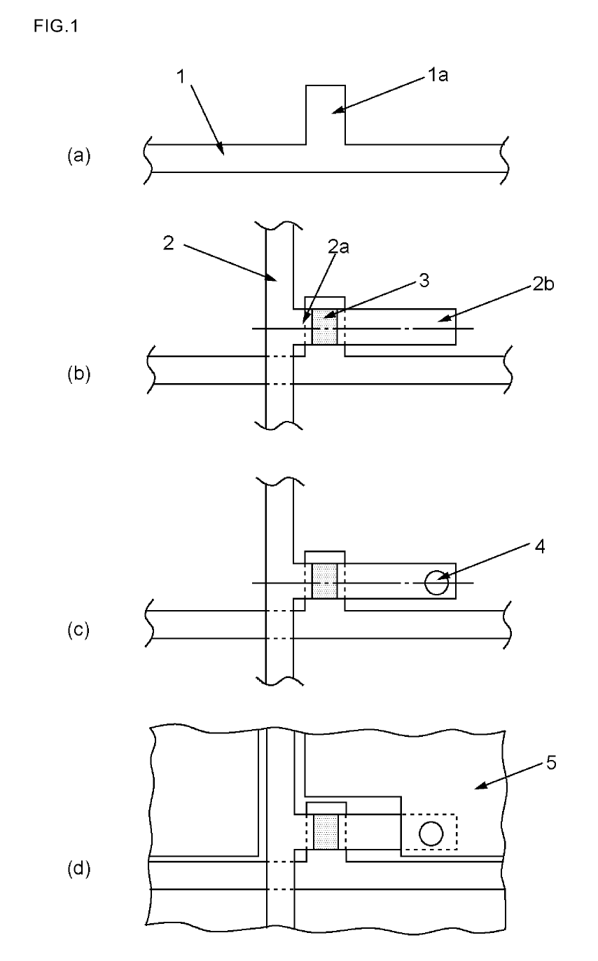

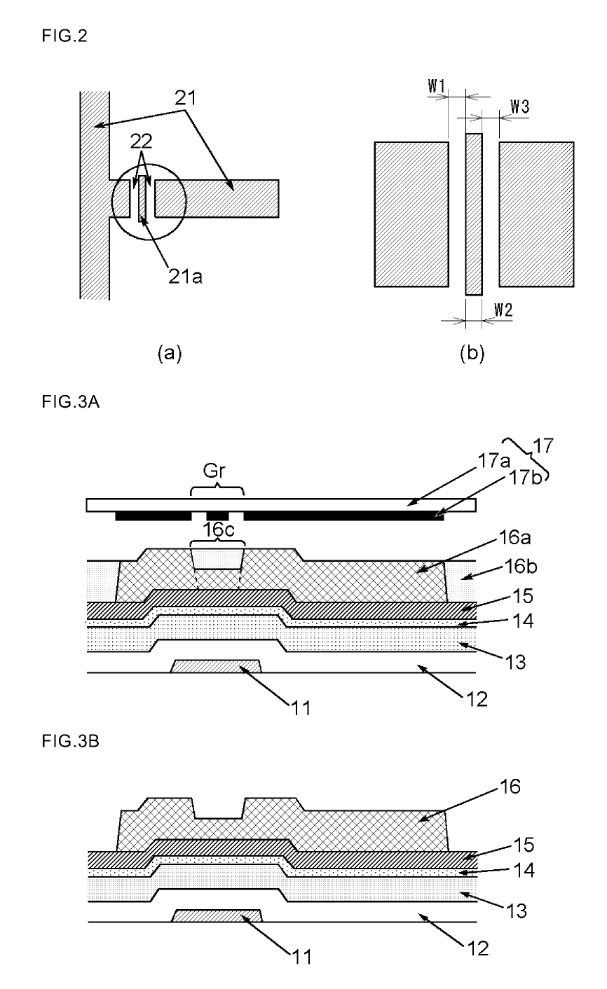

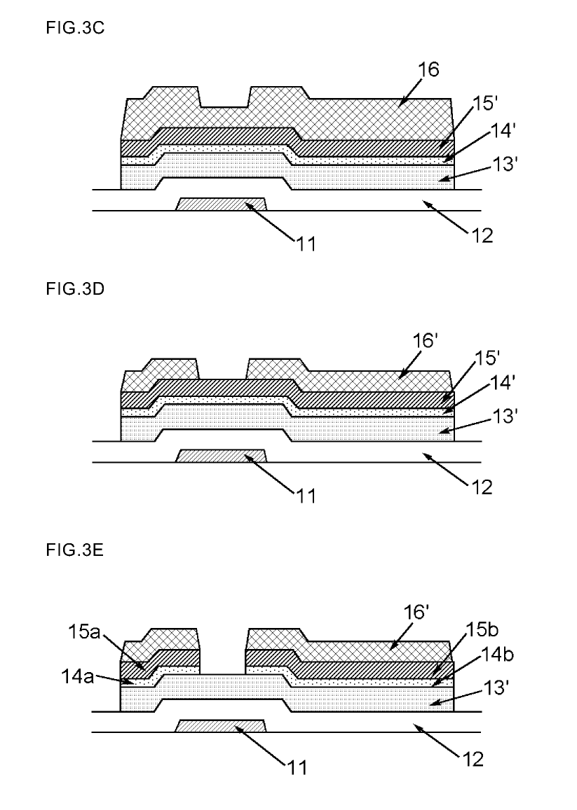

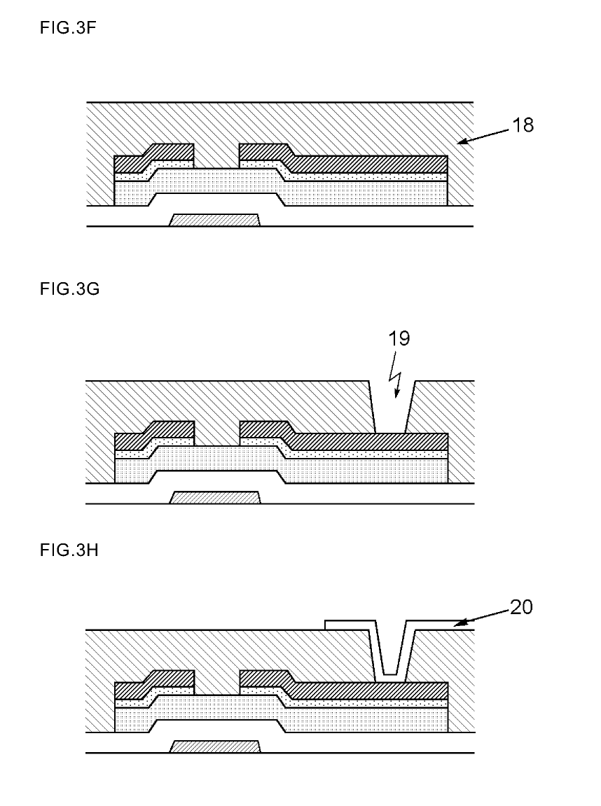

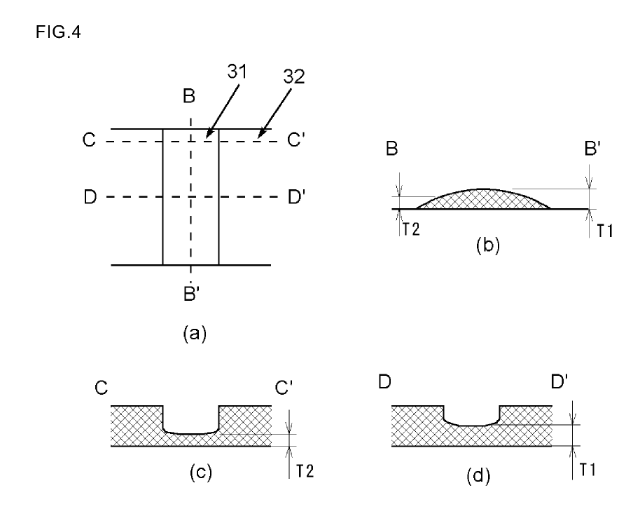

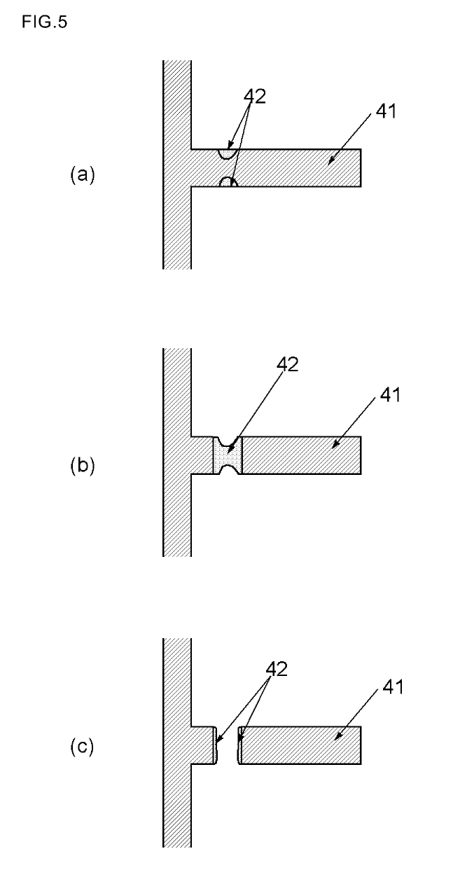

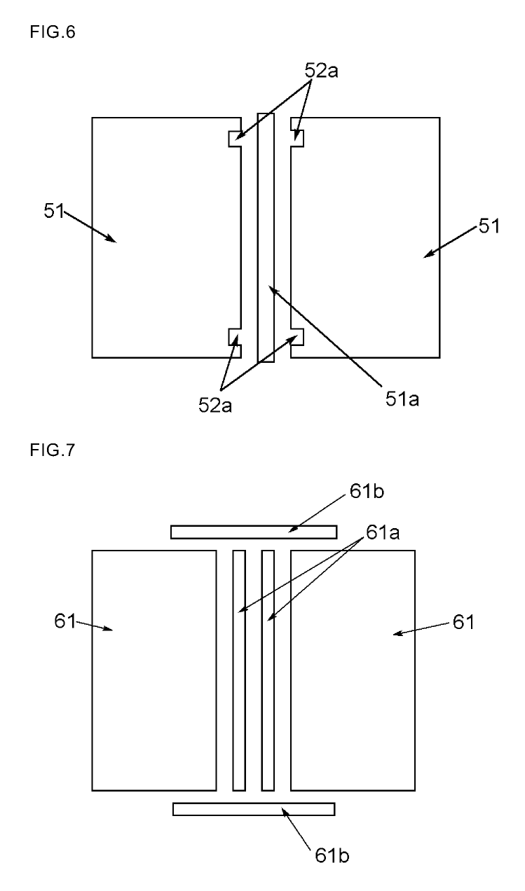

First, a film of metal such as Cr, Mo, Al or alloy thereof is formed on a transparent glass substrate and gate wiring 1, gate electrode 1a and a gate terminal (not shown) are formed in a first photolithography process (FIG. 1(a)). Then, as shown in a section view of FIG. 3A, SiNx film 12 to be a gate insulation film, a-Si layer 12 to be a semiconductor layer, n⁺a-Si layer 14 to be an ohmic contact layer, and metal layer 15 such as Cr, Mo, Al or alloy thereof are formed on gate electrode 11 by a CVD method and a sputtering method, respectively. Subsequently, a source electrode, a drain electrode, a drain wiring, a drain terminal (not shown) and an island are sequentially formed in a second photolithography process using a gray-tone mask.

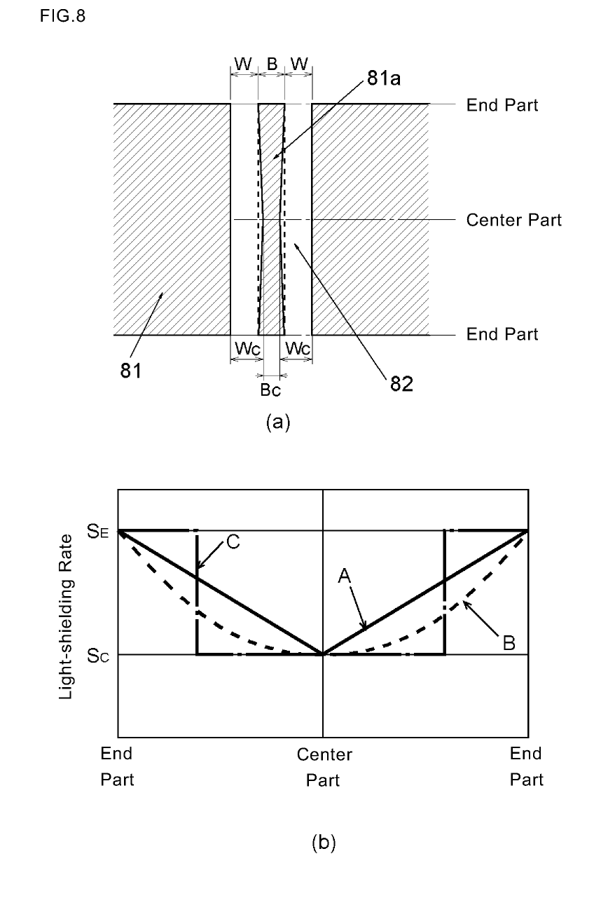

The second photolithography process will be more specifically described. The second photolithography process uses a gray-tone mask. The gray-tone mask used in the second photolithography process has a gray-tone pattern arranged between source and drain electrodes, i.e., on a part corresponding to a channel area. As shown in FIG. 8(a), a width “W” of slit-type transmissive patterns (spaces) 82 positioned at both sides of a intermediate light-shielding fine pattern 81a is preferably about 1.0-1.6 μm when a resultant channel length is 6 μm and a resolution limit of an exposure apparatus is about 3.5-4.0 μm. In this example, a shape of light-shielding fine pattern 81a is patterned in such a way that both ends thereof are wider than a center. Light-shielding fine pattern 81a has preferably dimensions that a width Bc of a central constricted part is 1.0-1.2 μm and a width B of widened parts of both ends is about 1.2-1.6 μm. In this example, when the width W of the slit-type transmissive pattern is 1.4 μm and the width B of the light-shielding fine pattern is 1.4 μm, the light-shielding rate at the ends (S_{E}) is about 33%. When the width B_{C} of the light-shielding fine pattern at the center is 1.0 μm, the width W_{C} of the slit-type transmissive pattern at the center is 1.6 μm and the light-shielding rate at the center (S_{C}) is about 24%. In addition, the ratio of light-shielding rates S_{E}/S_{C} is about 1.4

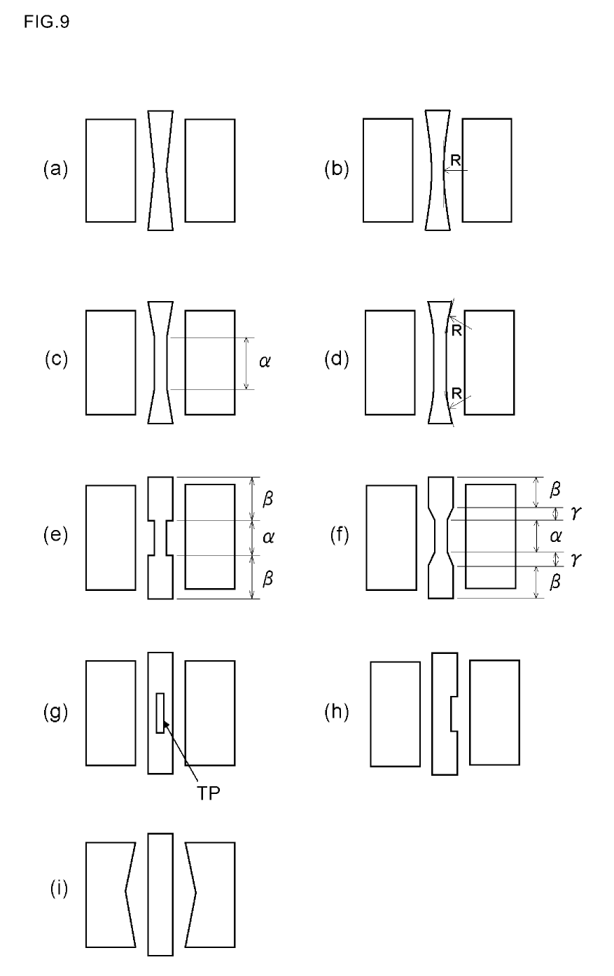

The pattern shape of the gray-tone area is preferably one of (a) to (i) of FIG. 9 or a shape similar thereto. In FIGS. 9(a) and 9(b), the light-shielding fine pattern has a width variation that is gradually narrowed toward a center from both ends of long sides. In FIG. 9(a), the width is linearly narrowed. In FIG. 9(b), the width is narrowed in a curve shape (arc shape) having a predetermined curvature R. In FIGS. 9(c) and 9(d), a first area (α), in which a central width is narrowed into a predetermined width, is provided. The width is narrowed linearly or curvilinearly toward the first area (α) from both ends, as FIGS. 9(a) and 9(b). FIG. 9(e) shows an intermediate light-shielding fine pattern having second areas (β) of a predetermined width from both ends and a first area (α) narrowed into a predetermined width. FIG. 9(f) shows a light-shielding fine pattern having third areas (γ) of a width gradually narrowed as shown in FIGS. 9(a) and 9(b) between the first area (α) and the second areas (β) as shown in FIG. 9(e). FIG. 9(g) shows an example in which a center of the light-shielding fine pattern is perforated to arrange a second transmissive pattern (TP). In all the examples, the light-shielding fine pattern is axial-symmetrically formed about the longitudinal central axis thereof. However, the invention is not limited thereto. In other words, the light-shielding fine pattern can be asymmetrically formed as shown in FIG. 9(h). Further, both long sides can be asymmetrically recessed. In addition, as shown in FIG. 9(i), by recessing the light-shielding patterns (source and drain electrode patterns) of the whole light-shielding parts positioned at both sides of the gray-tone area, it is possible to increase a ratio of the slit-type transmissive pattern to the light-shielding fine pattern at the center of the channel part than the ends. Meanwhile, when the source and drain electrode patterns are recesses as shown in FIG. 9(i), it is preferred to gently recess the patterns in a linear or curve shape toward the centers from both ends so as to restrain a final result of a channel length, which is an important factor to decide the characteristics of a transistor, from being varied. In addition, by protruding both ends of the light-shielding fine pattern beyond the light-shielding patterns of the whole light-shielding parts, which will be wiring layer patterns, it is possible to further prevent the terminal bending, which is caused due to the fact that the resist film thickness is thinner at the ends of the channel part by the diffraction of light from the whole transmissive part. It is preferred that each of the protrusions of both ends of the light-shielding fine pattern is about 0.1 to 0.5 μm.

The above mask is formed into a desired pattern by depositing light-shielding material such as metal film of Cr and the like on a transparent substrate of quartz glass and the like and exposing it with a known method, for example electron beam exposure apparatus.

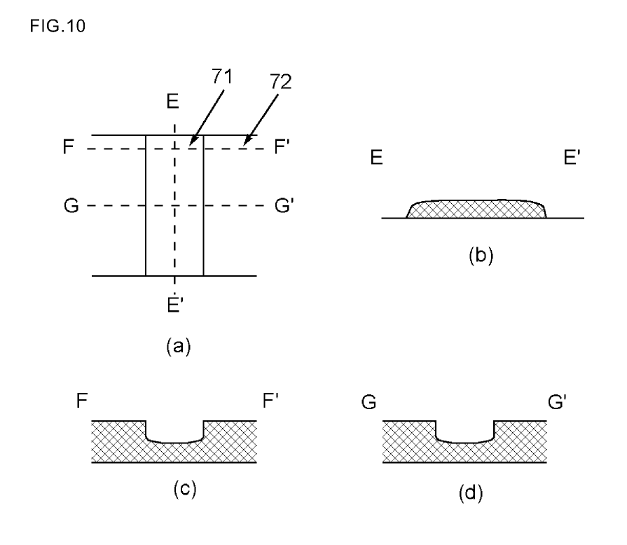

When the resist is coated on a substrate and exposed/developed with the above mask, the resist of an initial film thickness remains at parts to be a source electrode, a drain electrode, a drain wiring and a drain terminal, the resist of a half film thickness uniformly remains at a part to be a channel of transistor and the other resist is removed at the other parts. FIG. 10(a) shows a plan view showing the vicinity of the channel part, and FIGS. 10(b), (c) and (d) show sectional views taken along the lines E-E′, F-F′ and G-G′. As shown in the E-E′ section that is a section of the resist film thickness part of the channel width direction, the resist film thickness is almost uniform to the ends from the center. In addition, when comparing the F-F′ section of the channel part end and the G-G′ section of the center, which are the resist sections of the channel length direction, both have a shape that is almost same.

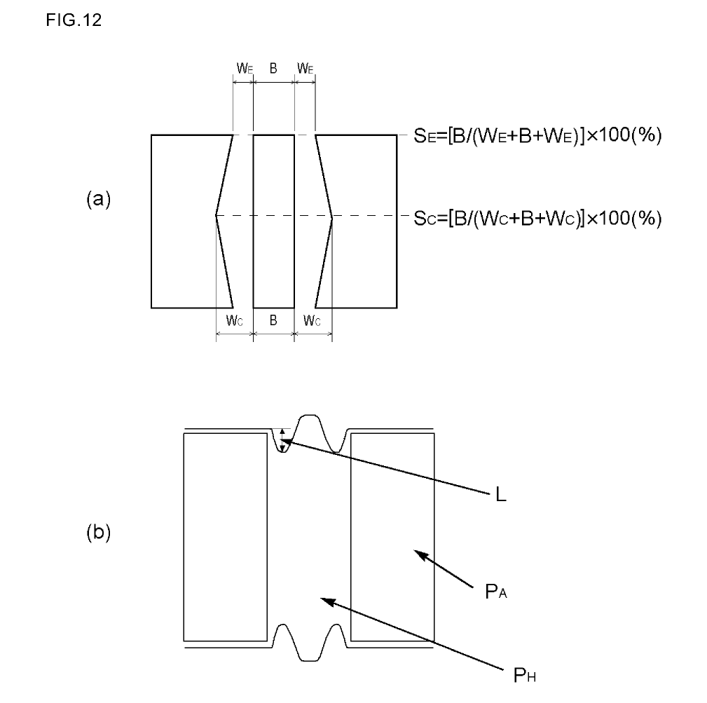

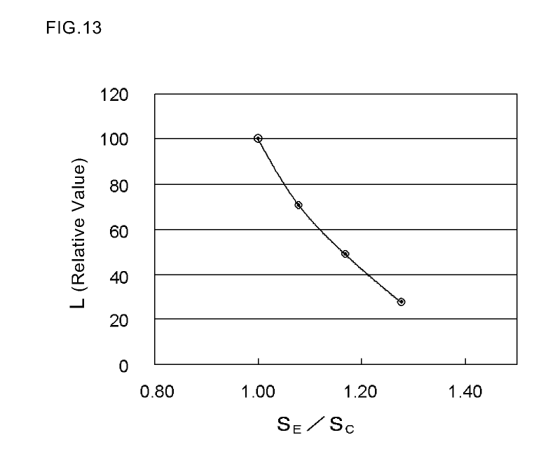

Here, an effect of this exemplary embodiment will be examined. FIG. 12(a) is a view illustrating definitions of a light-shielding rate and a ratio of light-shielding rates. FIG. 12(a) is the gray-tone pattern shown in FIG. 9(i), in which the width B of the light-shielding fine pattern is constant, the light-shielding rate S_{E} of the channel end is denoted as [B/(WE+B+WE)]×100(%) and the light-shielding rate S_{C} of the channel center is denoted as [B/(WC+B+WC)]×100(%). FIG. 12(b) is a view of a resist pattern illustrating a definition of an amount of constriction. A length: L of a part in which the half film thickness pattern: P_{H} sandwiched between the whole film thickness patterns: P_{A} is retreated from a pattern edge is an amount of constriction. FIG. 13 is a graph showing a relation between a ratio of light-shielding rates (S_{E}/S_{C}) and an amount of constriction (L). The amount of constriction is shown as a relative value that is 100 when the ratio of light-shielding rates is 1.00. When a mask having a pattern of a light-shielding rate most suitable for a gray-tone part is exposed with an optimal exposure, i.e., an exposure enabling the whole light-shielding part to be patterned into a designed line width, it is possible to obtain a half tone resist pattern of a desired film thickness over an entire range of the gray-tone part, i.e., from the longitudinal ends to the center thereof. The larger the ratio of light-shielding rates, i.e., the higher a ratio of the slit-type transmissive patterns to the light-shielding pattern at the channel center of the gray-tone pattern than the channel ends according to the invention, the amount of constriction becomes smaller. The ratio of light-shielding rates is preferably 1.1 or more, more preferably 1.2 or more. Meanwhile, since both the widths of the slit-type transmissive pattern and the light-shielding fine pattern are a submarginal resolution provided by an exposure apparatus and the minimum width of the light-shielding fine pattern is limited by a manufacturing method, the upper limit of the ratio of light-shielding rates is naturally limited. As a result, the uniformity of the half film thickness pattern is improved, the wider and sufficient half film thickness pattern is formed in the channel area and the manufacturing yield is increased.

Then, as shown in FIG. 3B, metal layer 15, n⁺a-Si layer 14 and a-Si layer 13 are etched by using first resist pattern 16 having the half film thickness as a mask, so that deposition structures 13′, 14′, 15′ to be a source electrode, a drain electrode, a drain wiring and a drain terminal are formed (FIG. 3C). Then, the half film thickness resist of the channel part is removed through the O₂ ashing, so that second resist pattern 16′ is formed (FIG. 3D). Subsequently, a second etching of metal layer 15′ is subjected by removing the resist of the half film thickness part to expose the metal and removing the metal at the exposure part. Furthermore, n⁺a-Si layer 14′ is etched to process the channel part (FIG. 3E). Finally, the resist is removed to complete the second photolithography process.

Further, passivation SiNx film 18 is formed by the CVD method (FIG. 3F) and an openings (not shown) of the gate and the drain terminal part and contact holes 4, 19 on the source electrode are formed in the third photolithography process (FIG. 1(c) and FIG. 3G). Then, a film of ITO is formed by the sputtering method, and pixel electrodes 5, 20 are formed in the fourth photolithography process to complete an array substrate (FIG. 1(d) and FIG. 3H).

### Exemplary Embodiment 2

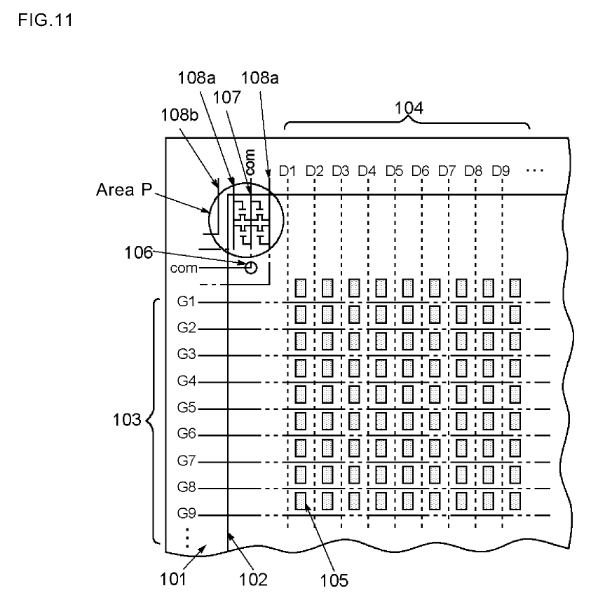

The liquid crystal display holds a liquid crystal layer between active matrix substrate 101 including a plurality of pixel electrodes formed thereon and opposite substrate 102 including opposite electrodes formed thereon. As shown in FIG. 11, active matrix substrate 101 includes a plurality of scanning lines (G1 to G9, xxx) and a plurality of data lines 104 (D1 to D9, xxx) arranged to intersect each other, and includes a plurality of pixel electrodes 105 arranged in areas surrounded by scanning lines 103 and data lines 104. Scanning lines 103 and data lines 104 are connected to pixel electrodes 105 via the pixel transistor as described in the exemplary embodiment 1.

In addition, a wiring pattern for a driving IC that is mounted in a COG or COF type is arranged in an area (P) of the vicinity of active matrix substrate 101. The wiring pattern is a control signal wiring and/or power supply wiring for a driving IC. The wiring pattern includes a plurality of wirings 108a, 108b. In addition, transfer pad 106, which applies a common potential to the opposite electrodes of opposite substrate 102, is also arranged in the area (P). Further, common wiring 107 connected to transfer pad 106 is also arranged. Wirings 108a, 108b and common wiring 107 are arranged to be parallel with each other. In addition, a protection transistor, which is an example of electrostatic protecting means, is connected between wirings 108a and common wiring 107. The protection transistor has a structure in which a gate and a source electrode are commonly connected therebetween, and is connected forward and backward, respectively. The details of the protection transistor are disclosed in a Japanese Unexamined Patent Publication No. 2006-308803, for example.

The protection transistor in the area (P) is formed as the pixel transistor described in the exemplary embodiment 1. However, effective channel length and channel width thereof are different from those of the pixel transistor in many times. It is possible that the gray-tone pattern part of the invention is arranged only in an area (for example, the protection transistor area of the area (P)) in which the half film thickness uniformity of resist to be formed is not good by using a mask having the fine pattern of the invention and the gray-tone pattern part of the prior art is arranged in the other areas (for example, pixel transistor area). It is needless to say that a mask having the gray-tone pattern part of the invention can be used to form the protection transistor and the pixel transistor.

Needless to say, pixel electrode 20 as shown in FIG. 3H is not formed in the protection transistor area.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

### INDUSTRIAL APPLICABILITY

The method of manufacturing a TFT substrate of a liquid crystal display has been described as an example. However, the invention is not limited thereto. For example, the invention can be used for uses requiring the uniformity of the half film thickness part.

In addition, although the above exemplary embodiments have described that one light-shielding fine pattern is sandwiched between the slit-type transparent patterns, a plurality of light-shielding fine patterns may be included.

### DESCRIPTION OF REFERENCE NUMERALS

1: gate wiring
   1a: gate electrode
2: drain wiring
   2a: drain electrode
   2b: source electrode
3: island part
4: source contact
5: pixel electrode
11: gate electrode
12: gate insulation film (SiNx)
13: semiconductor layer (a-Si)
14: ohmic contact layer (n⁺a-Si)
15: metal layer
16: first resist mask
   16a: non-exposed area
   16b: entirely exposed area
   16c: half exposed area (half film thickness part)
16′: second resist mask
17: gray-tone mask
   17a: transparent mask
   17b: light-shielding film pattern
18: passivation SiNx film
19: source contact hole
20: pixel electrode
81: light-shielding pattern (entire light-shielding part)
   81a: fine pattern
82: slit (light-transmissive part)

What is claimed is:

1. An exposure mask including a light-shielding pattern on a transparent substrate in which a gray-tone area is provided to at least a part of the light-shielding pattern,
the gray-tone area comprising an oblong light-shielding pattern having a width of a submarginal resolution provided by an exposure apparatus and said oblong light-shielding pattern is sandwiched between both of oblong slit-type transmissive patterns having a width of a submarginal resolution provided by an exposure apparatus,
wherein a light-shielding rate of the gray-tone area is gradually reduced toward a center of the oblong light-shielding pattern from longitudinal ends thereof.

2. The exposure mask according to claim 1, wherein the width of the oblong light-shielding pattern, perpendicular to a longitudinal direction, is narrower at a center of long sides of the oblong light-shielding pattern than the widths of both ends of the long sides.

3. The exposure mask according to claim 2, wherein the width of oblong light-shielding pattern is a pattern, perpendicular to a longitudinal direction, is gradually narrowed toward the center of the long sides from the widths of both ends of the long sides and is bilateral-symmetrical.

4. The exposure mask according to claim 2, wherein the oblong light-shielding pattern sandwiched between the slit-type transmissive patterns is a pattern in which the width of the oblong light-shielding pattern, perpendicular to a longitudinal direction, is gradually narrowed toward the center of the long sides from the widths of both ends of the long sides and is bilateral-asymmetrical.

5. The exposure mask according to claim 1, wherein both centers of light-shielding patterns positioned at both sides of the gray-tone area, the both centers being opposite, via slit transmissive patterns, to longitudinal sides of the oblong light-shielding pattern, are more recessed than both ends of the light-shielding patterns positioned at both sides in a direction distant from the oblong light-shielding pattern.

6. The exposure mask according to claim 1, wherein a longitudinal center of the oblong light-shielding pattern is provided with a transmissive pattern.

7. A method of manufacturing a thin film transistor substrate comprising:
sequentially forming a semiconductor layer and a wiring material layer on a substrate;
forming a resist film on the wiring material layer, and collectively forming overall film thickness patterns to be source and drain wiring patterns and a half film thickness pattern to be an island pattern of an active area on the resist film by using a gray-tone mask;
etching the wiring material layer and the semiconductor layer by using the resist film having the patterns formed thereon as a mask;
reducing a film thickness of the resist film to remove a resist of the half film thickness pattern part and thus to expose the wiring material layer of the half film thickness pattern part; and
etching the wiring material layer by using the remaining resist film as a mask and exposing the semiconductor layer to be an island of an active area,
wherein the gray-tone mask is an exposure mask including a light-shielding pattern on a transparent substrate in which a gray-tone area is provided to at least a part of the light-shielding pattern, the gray-tone area comprising an oblong light-shielding pattern having a width of a submarginal resolution provided by an exposure apparatus and sandwiched between oblong slit-type transmissive patterns having a width of a submarginal resolution provided by an exposure apparatus, and wherein a light-shielding rate of the gray-tone area is gradually reduced toward a center of the oblong light-shielding pattern from longitudinal ends thereof.

8. The method according to claim 7, wherein the substrate is a substrate comprising a gate wiring layer including a gate electrode and a gate insulation film formed on the gate wiring layer.

9. The method according to claim 7, wherein the gray-tone mask is patterned in such a way that a width perpendicular to a longitudinal direction is narrower at a center of long sides of the oblong light-shielding pattern than both ends of the long sides.

10. The method according to claim 9, wherein the oblong light-shielding pattern is a pattern in which a width perpendicular to a longitudinal direction is gradually narrowed toward the center of the long sides from both ends of the long sides and is bilateral-symmetrical.

11. The method according to claim 9, wherein the oblong light-shielding pattern sandwiched between the slit-type transmissive patterns is a pattern in which a width perpendicular to a longitudinal direction is gradually narrowed toward the center of the long sides from both ends of the long sides and is bilateral-asymmetrical.

12. The method according to claim 7, wherein the gray-tone mask comprises such a pattern that centers of the light-shielding patterns positioned at both sides of the gray-tone area, the centers being opposite to longitudinal sides of the oblong light-shielding fine pattern, are more recessed than both ends in a direction distant from the oblong light-shielding pattern.

13. The method according to claim 7, wherein the gray-tone mask provides a transmissive pattern to a longitudinal center of the oblong light-shielding pattern.

14. A liquid crystal display comprising a thin film transistor substrate manufactured by the method defined in claim 7.

15. A liquid crystal display comprising a thin film transistor substrate manufactured by the method defined in claim 8.

16. A liquid crystal display comprising a thin film transistor substrate manufactured by the method defined in claim 9.

17. A liquid crystal display comprising a thin film transistor substrate manufactured by the method defined in claim 10.

18. A liquid crystal display comprising a thin film transistor substrate manufactured by the method defined in claim 11.

19. A liquid crystal display comprising a thin film transistor substrate manufactured by the method defined in claim 12.

20. A liquid crystal display comprising a thin film transistor substrate manufactured by the method defined in claim 13.
